(19) United States
(12) Patent Application Publication
(10) Pub. No.: US 2006/0286692 A1
(43) Pub. Date: Dec. 21, 2006

(54) Method for manufacturing semiconductor element, apparatus for manufacturing semiconductor element and semiconductor element

(76) Inventors: Michifumi Nagawa, Fujimi (JP); Tsuyoshi Kaneko, Shimosuwa (JP); Atsushi Sato, Azumino (JP); Hikaru Iwai, Tatsuno (JP)

Correspondence Address: HARNESS, DICKEY & PIERCE, P.L.C., P.O. BOX 828, BLOOMFIELD HILLS, MI, 48303, US

(21) Appl. No.: 11/358,895

(22) Filed: Feb. 20, 2006

(30) Foreign Application Priority Data
Mar. 25, 2005 (JP) 2005-088140
Oct. 4, 2005 (JP) 2005-290785

(51) Int. Cl. H01L 21/00; H01S 3/08

(52) U.S. Cl. 438/22; 372/96

(57) ABSTRACT

A method for manufacturing a semiconductor element includes an oxidation step of forming an oxidized layer in a semiconductor substrate by an oxidizing gas, wherein the oxidation step is conducted for the semiconductor substrate in a plurality of divided steps.

The entire disclosure of Japanese Patent Application No. 2005-088140, filed, Mar. 25, 2005 and No. 2005-290785, filed Oct. 4, 2005 are expressly incorporated by reference herein.

### BACKGROUND

1. Technical Field

The present invention relates to methods for manufacturing semiconductor elements, apparatuses for manufacturing semiconductor elements, and semiconductor elements.

2. Related Art

Recently, there are increasing demands for optical semiconductor elements in the fields of optical communications and optical recording. Also, surface-emitting lasers (VCSEL), which are one of optical semiconductor elements, are characterized by their capability of high-speed operations and low power consumption, and are thus attracting attention along with the increase in the amount of data communications. Also, surface-emitting lasers can be readily tested in the manufacturing process, and are more advantageous because they are inexpensive than edge-emitting lasers. In order to best use these characteristics of surface-emitting lasers, it is desired to improve the yield without installing expensive production facility in the manufacturing process.

It can be said that oxidized constricting type surface-emitting lasers are simpler and have higher reliability than other types of surface-emitting lasers. An oxidized constricting type surface-emitting laser has a columnar section formed with multilayer films which compose at least a part of its resonator, in which an oxidized constricting layer is formed by oxidizing one of the films from the side surface of the columnar section. The density of current flowing through the columnar section is increased by the oxidized constricting layer, thereby improving the efficiency of laser output. The oxidized constricting layer may have a plane that is in a ring-shape. An oxide constricting radius, which is a radius of an inner circumference of the ring shape of the oxidized constricting layer, is the most important parameter that determines the characteristics of the oxidized constricting type surface-emitting laser.

It is noted here that the size of the oxide constricting radius is determined by the oxidation time, and the oxidation amount (the oxide constricting radius) is proportional to the oxidation time. However, due to slight differences in the composition or the film thickness of oxidized constricting layers, the oxidation rate may become slightly different among wafers, and thus the oxide constricting radii may become slightly different from one another.

For this reason, techniques for accurately controlling the oxidation amount, and techniques for measuring in real time the progress of oxidation have been proposed. For example, Japanese Laid-open patent application JP-A-10-144682 has proposed a technique in which, before conducting a selective oxidation to form an oxidized constricting layer, an oxidized surface of GaAs is removed to more accurately control the progress of oxidation.

Also, for example, Japanese Laid-open patent application JP-A-2000-95934 has proposed a method in which, besides an ordinary resonator configuration, a striped pattern for measuring the oxidation rate is provided, and the reflectivity of the pattern region is measured in the oxidation furnace to thereby determine the degree of oxidation progress.

However, JP-A-10-144682 entails a problem because differences in the oxidation rate due to differences in the composition or the film thickness of oxidized layers among wafers cannot be absorbed by the described technique.

Further, with the technique described in JP-A-2000-95934, because of the provision of a pattern for monitoring the oxidation rate, a resonator cannot be disposed near the pattern on a substrate. Because the oxidation rate sensitively changes according to the composition of a surrounding area, the oxidation rate may slightly change when the resonator is disposed near the pattern, which makes it difficult to accurately measure the amount of oxidation. Also, the technique described in JP-A-2000-95934 has a problem in that, because a pattern for measuring the oxidation rate needs to be provided on a substrate, the area that can be used for forming a surface-emitting laser element is limited.

### SUMMARY

In accordance with an advantage of some aspects of the invention, there are provided a method for manufacturing a semiconductor element, an apparatus for manufacturing a semiconductor element and a semiconductor element, in which oxidized layers that form components of the semiconductor elements can be accurately fabricated.

Also, in accordance with another advantage of some aspects of the invention, there are provided a method for manufacturing a semiconductor element, an apparatus for manufacturing a semiconductor element and a semiconductor element, in which oxide constricting apertures in surface-emitting lasers are accurately formed.

Further, in accordance with still another advantage of some aspects of the invention, there are provided a method for manufacturing a semiconductor element, an apparatus for manufacturing a semiconductor element and a semiconductor element, in which surface-emitting lasers having uniform and accurate oxide constricting apertures can be fabricated while suppressing complication and difficulty in the process management and/or the manufacturing apparatus.

In accordance with an embodiment of the invention, a method for manufacturing a semiconductor element has an oxidation process of forming an oxidized layer in a semiconductor substrate by an oxidizing gas, wherein the oxidation process is conducted for the semiconductor substrate in a plurality of divided steps. According to the present embodiment, because the oxidation process is conducted in a plurality of divided steps, the uniformity and accuracy of the oxidation result can be improved, compared to the case where a continuous single-step oxidation is conducted. For example, among a plurality of oxidation steps, the oxidation configuration of one of the oxidation steps may be made different from the oxidation configuration of another of the oxidation steps. By this, the oxidation state of each of sections can be made uniform entirely across a semiconductor substrate such as a wafer. Also, according to the present embodiment, based on an oxidation result of an oxidation step, the method, parameters and the like of another oxidation step to be conducted later can be controlled. Therefore, according to the present embodiment, an oxidized layer that is a component of a semiconductor element can be accurately fabricated by the entirety of the plurality of oxidation steps.

Also, in the method for manufacturing a semiconductor element in accordance with an aspect of the embodiment of the invention, the plurality of oxidation steps includes a first oxidation step and a second oxidation step, wherein the direction of flow of oxidizing gas with respect to the semiconductor substrate in the first oxidation step may preferably be different from the direction of flow of oxidizing gas with respect to the semiconductor substrate in the second oxidation step.

In accordance with the present embodiment, an oxidation treatment can be uniformly conducted entirely across the semiconductor substrate. The amount of oxidation in a portion of the semiconductor substrate located upstream of oxidizing gas is generally greater than that of a portion located downstream. This is because the temperature of the oxidizing gas flowing upstream is higher, and the oxidation rate is proportional to the temperature. According to the present embodiment, the direction of oxidizing gas flow with respect to the semiconductor substrate is changed between the first oxidation step and the second oxidation step, such that the positional relation between the upstream and the downstream of the oxidizing gas at each of the sections across the semiconductor substrate can be reversed. Thus, an oxidation treatment can be uniformly conducted entirely across a semiconductor substrate, such that oxidized layers that are components of semiconductor elements can be accurately fabricated.

Also, in the method for manufacturing a semiconductor element in accordance with an aspect of the embodiment of the invention, in the first oxidation step and the second oxidation step, the flow direction of the oxidizing gas may preferably be different through 180 degrees from each other.

According to the present embodiment, the positional relation between the upstream and the downstream of the oxidizing gas at each of the sections across the semiconductor substrate can be accurately reversed. Thus, in accordance with the present embodiment, an oxidation treatment can be uniformly conducted entirely across a semiconductor substrate, such that oxidized layers that are components of semiconductor elements can be accurately and readily fabricated.

Also, in the method for manufacturing a semiconductor element in accordance with an aspect of the embodiment of the invention, the oxidation process may preferably include the steps of inserting the semiconductor substrate in an oxidation furnace and flowing an oxidizing gas in the oxidation furnace, wherein the semiconductor substrate may be removed from the oxidation furnace after the first oxidation step, the semiconductor substrate may be placed again in the oxidation furnace in a manner that the orientation of the semiconductor substrate is 180 degrees different from the orientation of the semiconductor substrate in the oxidation furnace in the first oxidation step, and then the second oxidation step may preferably be conducted.

According to the present embodiment, the flow direction of the oxidizing gas can be changed through 180 degrees with respect to the semiconductor substrate without making a special modification on the manufacturing apparatus such as the oxidation furnace. It is noted that the oxidation rate is greatly influenced by the temperature of the stage within the oxidation furnace, the oxidation atmosphere and the temperature distribution. Also, the oxidation rate does not greatly change even when the oxidation process is stopped halfway and restarted, and the change in the oxidation rate is small between the case where the oxidation process is conducted in a continuous single step and the case where the oxidation process is conducted in a plurality of divided steps. Therefore, in accordance with the present embodiment, an oxidation treatment can be uniformly applied entirely across a semiconductor substrate by the entirety of the plurality of oxidation steps, and oxidized layers that are to become components of semiconductor elements can be accurately fabricated at low cost.

In the method for manufacturing a semiconductor element in accordance with an aspect of the embodiment of the invention, a period to interrupt formation of an oxidized layer by the oxidizing gas may preferably be provided between the first oxidation step and the second oxidation step.

According to the present embodiment, because a period for interrupting the oxidation step is provided between the first oxidation step and the second oxidation step, the orientation of the semiconductor substrate can be changed when the temperature within the oxidation furnace is lowered due to the interruption. Therefore, a uniform oxidation treatment can be conducted without using difficult controls in a water vapor atmosphere at 400° C., such as, controls of a stage rotation mechanism and temperature management of an oxidation apparatus such as an oxidation furnace, and therefore surface-emitting lasers having uniform oxide constricting apertures can be obtained.

In the method for manufacturing a semiconductor element in accordance with an aspect of the embodiment of the invention, the semiconductor substrate may preferably have a compound semiconductor layer, wherein the oxidized layer may preferably be formed in the compound semiconductor layer by the oxidation process.

According to the present embodiment, the oxidized layer disposed in the compound semiconductor layer can be accurately formed in a desired configuration.

In the method for manufacturing a semiconductor element in accordance with an aspect of the embodiment of the invention, the semiconductor element may preferably be a surface-emitting laser, and the oxidized layer may preferably define an oxidized constricting layer of the surface-emitting laser.

According to the present embodiment, an oxidized constricting layer in a surface-emitting laser can be accurately formed in a desired configuration. Therefore, a high-performance surface-emitting laser having a desired oxide constricting aperture can be manufactured with good yield.

Also, the method for manufacturing a semiconductor element in accordance with an aspect of the embodiment of the invention may preferably include a measurement step of inspecting a formed state of the oxidized layer during the plurality of oxidation steps.

Also, the method for manufacturing a semiconductor element in accordance with an aspect of the embodiment of the invention may preferably include adjusting parameters of the oxidation process to be conducted after the measurement step based on an inspection result of the measurement step.

According to the embodiment of the invention, parameters of one of the oxidation steps to be conducted after the measurement step can be controlled based on the measurement result obtained by the measurement step. As the parameters of the oxidation step, for example, the oxidation time of the oxidation step, the flow amount of the oxidizing gas, and the temperature of the oxidizing gas can be enumerated. Also, based on the measurement result obtained by the measurement step, the number of oxidation steps to be conducted thereafter can be controlled. Consequently, according to the present embodiment of the invention, a surface-emitting laser having a uniform and accurate oxide constricting aperture can be fabricated while complication and difficulty in the process management and the manufacturing apparatus can be suppressed.

In accordance with another embodiment of the invention, an apparatus for manufacturing a semiconductor element includes an oxidation furnace in which a semiconductor substrate is placed, wherein the oxidation furnace has a discharge port for discharging an oxidizing gas inside the oxidation furnace, and a substrate orientation changing device that changes the orientation of the semiconductor substrate inside the oxidation furnace with respect to the discharge port as a reference.

According to the present embodiment of the invention, the flow direction of the oxidizing gas with respect to the semiconductor substrate can be changed by the substrate orientation changing device. Accordingly, an oxidation treatment can be uniformly applied to the entire semiconductor substrate, such that oxidized layers that are to become components of semiconductor elements can be accurately fabricated.

Also, in the apparatus for manufacturing a semiconductor element in accordance with an aspect of the embodiment of the invention, the substrate orientation changing device may preferably take out the semiconductor substrate disposed inside the oxidation furnace from the oxidation furnace, change the orientation of the semiconductor substrate with respect to the discharge port through 180 degrees, and dispose the semiconductor substrate again in the oxidation furnace, during the oxidation process that is applied to the semiconductor substrate in the oxidation furnace.

According to the embodiment of the invention, an existing oxidation furnace can be used as the oxidation furnace, and the substrate orientation changing device can be disposed outside the oxidation furnace. Accordingly, the internal structure of an oxidation furnace that generally reaches high temperatures can be prevented from becoming complicated. Therefore, according to the embodiment of the invention, a manufacturing apparatus that can highly accurately fabricate oxidized layers can be provided at low cost.

Also, in the apparatus for manufacturing a semiconductor element in accordance with an aspect of the embodiment of the invention, the oxidation furnace may preferably stop discharging the oxidizing gas before the orientation of the semiconductor substrate is changed by the substrate orientation changing device, and restart discharging the oxidizing gas after the orientation of the semiconductor substrate is changed by the substrate orientation changing device.

According to the embodiment of the invention, when the orientation of the semiconductor substrate is changed by the substrate orientation changing device, the uniformity and accuracy of oxidation can be prevented from becoming inhibited due to a possible disturbance of the flow of the oxidizing gas.

Further, in the apparatus for manufacturing a semiconductor device in accordance with an aspect of the embodiment, the substrate orientation changing device may preferably include a stage that is disposed inside the oxidation furnace for mounting the semiconductor substrate thereon, a rotation device that changes the orientation of the stage with respect to the discharge port, and a control device that operates the rotation device when an internal temperature of the oxidation furnace is lowered to a predetermined value during the oxidation process applied to the semiconductor substrate.

According to the present embodiment, the orientation of the semiconductor substrate with respect to the flow direction of the oxidizing gas can be changed by the rotation device and the stage. Furthermore, in accordance with the present embodiment, the rotation device can be operated by the control device when the temperature inside the oxidation furnace is sufficiently lowered. Therefore, there is no need to compose a high-level apparatus that rotates a stage while performing a temperature management of the stage during an oxidation treatment at high temperatures. Consequently, according to the present embodiment, a semiconductor element manufacturing apparatus, which can accurately fabricate oxidized layers entirely across a semiconductor substrate, can be provided at low cost.

In accordance with another embodiment of the invention, a semiconductor element is fabricated by using the apparatus for manufacturing a semiconductor element described above.

According to the present embodiment, an efficient semiconductor element having an oxidized layer in a desired configuration can be provided at low cost.

Also, in the method for manufacturing a semiconductor element in accordance with another aspect of the embodiment of the invention, the plurality of oxidation steps may preferably include a first oxidation step, a second oxidation step that is performed after the first oxidation step, and a third oxidation step that is performed after the second oxidation step, wherein the flow direction of the oxidizing gas with respect to the semiconductor substrate in the first oxidation step is different from the flow direction of the oxidizing gas with respect to the semiconductor substrate in the second oxidation step, and a measurement step of inspecting a forming state of the oxidized layer is conducted before the third oxidation step.

According to the present embodiment, the oxidation step is divided in three steps, such that the oxidation time in the third oxidation step can be shortened, compared to that of each of steps in that case where the oxidation step is divided in two steps. Accordingly, errors in the oxidation time can be reduced. Also, the oxidation time of the third oxidation step can be finely adjusted based on the inspection result of the measurement step, and therefore an oxidized layer in a desired configuration can be more accurately fabricated.

Also, in the method for manufacturing a semiconductor element in accordance with another aspect of the embodiment of the invention, the oxidation time of the third oxidation step may preferably be shorter than the oxidation time of the first oxidation step.

According to the present embodiment, for example, a major portion of a designed oxidized layer can be formed by the first and second oxidation steps, and the configuration and amount of the oxidized layer can be finely adjusted by the third oxidation step. Consequently, according to the present embodiment, an oxidized layer can be more precisely formed while suppressing an increase in the manufacturing time.

Also, in the method for manufacturing a semiconductor element in accordance with another aspect of the embodiment of the invention, the semiconductor element may preferably be a surface-emitting laser, the surface-emitting laser may preferably have a columnar section having a trapezoidal cross-sectional shape, the oxidized layer defines an oxidized constricting layer that is formed inside the columnar section of the surface-emitting laser, wherein, in the first oxidation step, the oxidized layer may preferably be formed up to a position inside of a region shaded by a sloped side of the columnar section as the columnar section is viewed from above.

According to the present embodiment, an oxidized constricting layer of a surface-emitting laser can be accurately formed. As a method to confirm the formed state of the oxidized constricting layer of the surface-emitting laser, the columnar section may be observed from above by a microscope. With this method, it is difficult to observe the oxidized layer that is formed in a region shaded by the sloped side of the columnar section. However, according to the present embodiment, in the first oxidation step, the oxidized layer can be formed at least in an entire region shaded by the sloped side of the columnar section. Then, in the second oxidation step, a region other than the region shaded by the sloped side of the columnar section (i.e., a region that is inside the columnar section and can be well observed by a microscope) is oxidized. In this instance, the amount of oxidation (oxidation rate) in the second oxidation step can be accurately measured, such that the oxidized constricting layer of the surface-emitting laser can be accurately formed.

Also, in the method for manufacturing a semiconductor element in accordance with another aspect of the embodiment of the invention, the measurement step may preferably include inspecting at least a position of an end section of the oxidized layer formed by the first oxidation step and a position of an end section of the oxidized layer formed by the second oxidation step, and the third oxidation step may preferably be performed with parameters for oxidation being adjusted based on a measurement result of the measurement step.

According to the embodiment, the position of the end section of the oxidized layer formed by the first oxidation step, and the position of the end section of the oxidized layer formed by the second oxidation step can be well observed by a microscope or the like. Therefore, a starting point and an end point of oxidation in the second oxidation step can be accurately detected, such that the amount of oxidation (oxidation rate) can be accurately measured, and therefore the oxidized constricting layer of the surface-emitting laser can be accurately formed.

In accordance with another embodiment of the invention, a semiconductor element is manufactured by the method for manufacturing a semiconductor element described above.

According to the present embodiment, an efficient semiconductor element having an oxidized layer in a desired configuration can be provided at low cost.

### BRIEF DESCRIPTION OF THE DRAWINGS

FIG. 1 is a schematic cross-sectional view of a surface-emitting laser in accordance with an embodiment of the invention.

FIG. 2 shows schematic plan views showing a method for manufacturing a surface-emitting laser in accordance with an embodiment of the invention.

FIG. 3 is a plan view of an oxidized constricting layer formed by a first oxidation step of the manufacturing method.

FIG. 4 is a plan view of an oxidized constricting layer formed by the first oxidation step and a second oxidation step of the manufacturing method.

FIG. 5 is a schematic diagram of an oxidation amount inspection apparatus that is used in the manufacturing method.

FIG. 6 is a partially enlarged view of the oxidation amount inspection apparatus.

FIG. 7 shows schematic plan views showing a method for manufacturing a surface-emitting laser in accordance with another embodiment of the invention.

FIG. 8 shows plan views of oxidized constricting layers formed by respective steps of the manufacturing method.

FIG. 9 is a schematic cross-sectional view showing the manufacturing method.

FIG. 10 is a schematic cross-sectional view showing another example of a method for manufacturing a surface-emitting laser.

### DESCRIPTION OF EXEMPLARY EMBODIMENTS

A method for manufacturing a semiconductor element, an apparatus for manufacturing a semiconductor element, and a semiconductor element in accordance with embodiments of the invention are described with reference to the accompanying drawings. In the present embodiment, a surface-emitting laser is described as an example of the semiconductor element.

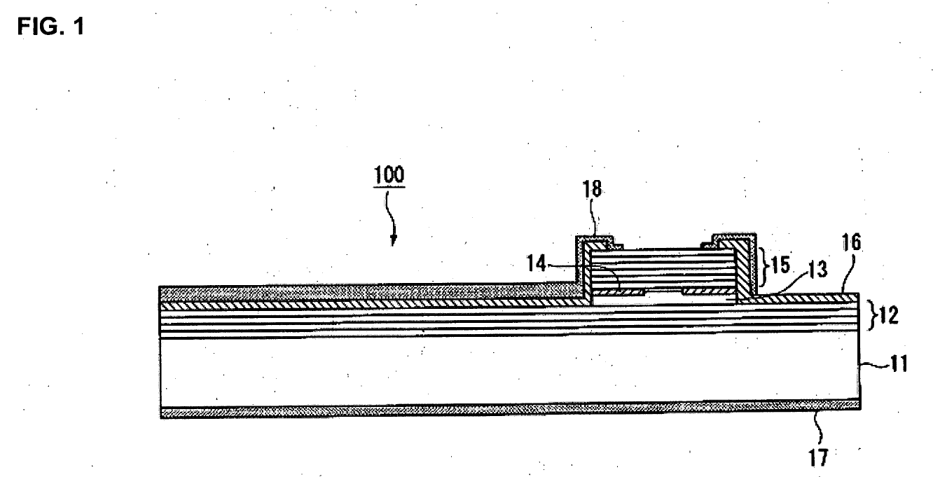

FIG. 1 is a schematic cross-sectional view of a surface-emitting laser in accordance with an embodiment of the invention. The surface-emitting laser 100 is manufactured by a method for manufacturing a semiconductor element in accordance with an embodiment of the invention. The surface-emitting laser 100 is composed of a semiconductor substrate 11, a lower DBR 12, an active layer 13, an oxidized constricting layer (current constricting layer) 14, an upper DBR 15, an insulation layer 16, a first electrode 17, and a second electrode 18.

The semiconductor substrate 11 is composed of a compound semiconductor, and may be composed of, for example, an n-type GaAs substrate. The lower DBR 12 is formed above the semiconductor substrate 11. The lower DBR 12 is formed from a reflection layer composed of alternately laminated layers of different refractive indexes. For example, the lower DBR 12 forms a distributed reflection multilayer mirror (DBR mirror) composed of 40 pairs of alternately laminated n-type Al_{0.0}Ga_{0.1}As layers and n-type Al_{0.15}Ga_{0.85}As layers. The active layer 13 is formed above the lower DBR 12. The active layer 13 is composed of, for example, GaAs well layers of 3 nm thick and Al_{0.3}Ga_{0.7}As barrier layers of 3 nm thick in which the well layers form a quantum well layer composed of three layers.

The upper DBR 15 is provided above the active layer 13. The upper DBR 15 is formed from a reflection layer of alternately laminated layers of different refractive indexes. For example, the lower DBR 15 composes a distributed reflection multilayer mirror (DBR mirror) composed of 25 pairs of alternately laminated p-type Al_{0.0}Ga_{0.1}As layers and p-type Al_{0.15}Ga_{0.85}As layers.

The lower DBR 12 may be formed to be n-type semiconductor, for example, by doping silicon (Si). The upper DBR 15 may be formed to be p-type semiconductor, for example, by doping carbon (C). The active layer 13 is not doped with an impurity. Accordingly, the lower DBR 12, the active layer 13 and the upper DBR 15 form a pin diode, and compose a resonator of the surface-emitting laser 100. The active layer 13 and the upper DBR 15 in the resonator form a cylindrical columnar section formed in a convex shape on an upper surface of the lower DBR 12 over the semiconductor substrate 11. It is noted that the lower DBR 12 may also be formed in a convex shape, and a portion of the lower DBR 12 on an upper side thereof may be formed to compose a part of the columnar section. An upper surface and a lower surface of the columnar section define a laser light emission surface of the surface-emitting laser. 100. The columnar section of the surface-emitting laser 100 may preferably have a cross-sectional shape that is trapezoidal.

The oxidized constricting layer 14 is disposed in the upper DBR 15 near a lower surface thereof The oxidized constricting layer 14 has a plane configuration that is a ring shape. A radius of an inner circumference of the ring shape defines an oxidized constricting radius (also referred to as an oxide constricting aperture diameter). The oxidized constricting layer 14 is a portion that is formed by an oxidation step of the method for manufacturing a surface-emitting type element in accordance with the present embodiment.

The oxidized constricting layer 14 is formed from a dielectric layer composed of, for example, an Al oxide as a main component. The oxidized constricting layer 14 narrows the flow area of a current flowing in the resonator of the surface-emitting laser 100 to thereby increase the current density. By increasing the current density, the surface-emitting laser 100 with a high performance, which can perform laser oscillation at a lower current, can be fabricated.

The oxidized constricting layer 14 may be formed through providing a layer that can be readily oxidized (a layer mainly containing Al, for example, an AlGaAs layer with its Al composition being 0.95% or higher) near the active layer, and conducting an oxidation reaction by using high-temperature water vapor (oxidizing gas) at about 400° C. By this, the layer that would readily be oxidized in the cylindrical columnar section is oxidized from the side surface of the columnar section, and the oxidized portion defines a ring shaped dielectric layer, which becomes the oxidized constricting layer 14.

The insulation layer 16 is a layer for insulating the second electrode 18 from the lower DBR 12 and the active layer 13. The first electrode 17 forms a cathode electrode of the surface-emitting laser 100. The second electrode 18 forms an anode electrode of the surface-emitting laser 100.

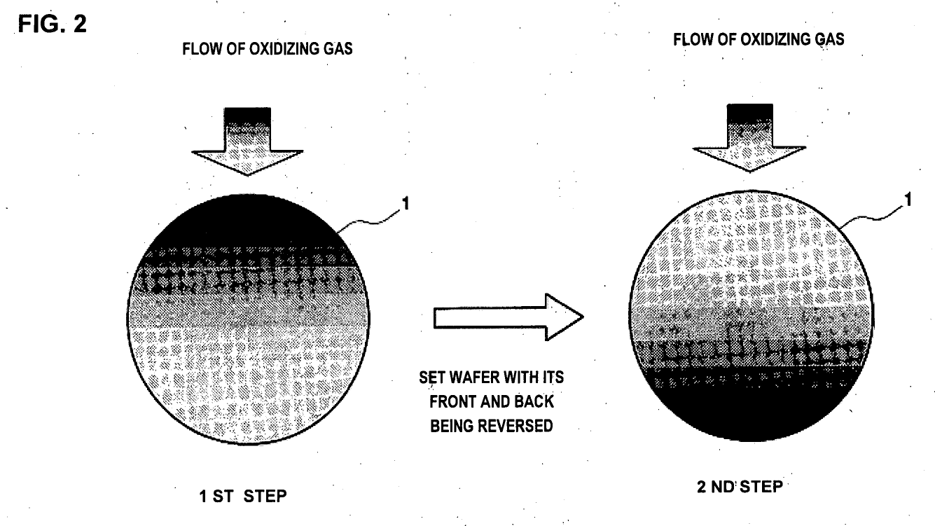

FIG. 2 schematically shows plan views showing a method for manufacturing a surface-emitting laser in accordance with an embodiment of the invention. FIG. 2 shows oxidation steps for forming the oxidized constricting layer 14 in the surface-emitting laser 100 shown in FIG. 1. A wafer 1 corresponds to the semiconductor substrate 11 shown in FIG. 1. It is assumed that the lower DBR 12, the active layer 13 and the upper DBR 15 composing each resonator of the surface-emitting laser 100 have already been formed on the wafer 1. Also, it is assumed that the cylindrical columnar section, which is formed from the active layer 13 and the upper DBR 15 protruding in a convex shape from the lower DBR 12, has already formed on the wafer 1. It is also assumed that such a columnar section has a very small size, and many of them are formed at various portions across the entire upper surface of the wafer 1. In other words, numerous resonators of surface-emitting lasers 100 are formed on the upper surface of the wafer 1.

Oxidizing gas indicated in FIG. 2 is a gas with which an oxidation treatment is applied to the wafer 1. In other words, the oxidizing gas is a gas for forming the oxidized constricting layer 14. For example, water vapor at about 400° C. may be used as the oxidizing gas. Then, the oxidizing gas is blown toward the side surface of the wafer 1, and the flow direction of the oxidizing gas is in parallel with the plane direction of the wafer 1.

The figure on the left side of FIG. 2 indicates a first oxidation step, and the figure on the right side of FIG. 2 indicates a second oxidation step. The first oxidation step is a first oxidation treatment, and the second oxidation step is a second oxidation treatment. The grayscale gradation shown on the wafer 1 in FIG. 2 indicates the degree of oxidation (the rate of oxidation or the amount of oxidation) at each section of the wafer 1. Darker areas indicate areas where the rate of oxidation is greater, and lighter areas indicate areas where the rate of oxidation is smaller. Accordingly, with the wafer 1 on the left side of FIG. 2, the more the flow of the oxidizing gas is located upstream (an upper side of the figure) across the entire plane surface of the wafer 1, the greater the rate of oxidation, and the more the flow is located downstream (a lower side of the figure), the smaller the rate of oxidation.

This happens because, when the oxidizing gas flows from the upper side in the figure to the lower side, as indicated in FIG. 1, a gradient occurs in the concentration and temperature of water vapor. In other words, the rate of oxidation is strongly influenced by the oxidation atmosphere (the concentration of water vapor) and the temperature (the temperature of water vapor, the temperature of the stage and the like), and is generally proportional to the concentration and temperature of water vapor. Therefore, if the oxidation step is to be completed only by the first oxidation step indicated on the left side of FIG. 2 (in the case of a conventional oxidation step), the oxidized constricting aperture diameter at the columnar section in an area with a greater rate of oxidation (darker portion) becomes smaller than the oxidized constricting aperture diameter at the columnar section in an area with a lower rate of oxidation.

It is noted here that, in general, the smaller the oxidized constricting aperture diameter, the smaller the threshold value of current that can oscillate the surface-emitting laser 100, and the more efficient the surface-emitting laser 100 becomes. Consequently, the surface-emitting laser 100 in an area with a greater rate of oxidation would have a lower threshold value of oscillation current than the surface-emitting laser 100 in an area with a lower rate of oxidation has.

Therefore, in accordance with the present embodiment, the first oxidation step indicated in FIG. 2 performs the oxidation treatment in one half of the entire amount of oxidation, and then the second oxidation step indicated in FIG. 2 performs the oxidation treatment in the other half. In other words, the oxidation process for forming the oxidized constricting layer 14 is divided in multiple steps and conducted on each one of the wafers 1.

Concretely, first, the wafer 1 is placed in an oxidation furnace (not shown), and the first oxidation step indicated on the left side of FIG. 2 is performed. By this, one half of the oxidation process for forming the oxidized constricting layer 14 is progressed. After the first oxidation step, supply of the oxidizing gas inside the oxidation furnace is stopped, thereby interrupting the oxidation process. Then, the wafer 1 is removed from the oxidation furnace, the wafer 1 is rotated through 180 degrees about a center axis orthogonal to the plane of the wafer 1 as a reference, and the wafer 1 in this state is inserted in the oxidation furnace again. By this, the wafer 1 is disposed in the oxidation furnace, rotated through 180 degrees (i.e., with its front and rear being inverted) with respect to the flow direction of oxidizing gas (i.e., the discharge port). Accordingly, as indicated on the right side of FIG. 2, the area with a smaller amount of oxidation is positioned in the upstream of the oxidizing gas flow, and the area with a greater amount of oxidation is positioned in the downstream of the oxidizing gas flow.

In this state, the second oxidation step is applied to the wafer 1. The second oxidation step is the same as the first oxidation step as to the discharge state of oxidizing gas in the oxidation furnace. In other words, the discharging position of the oxidizing gas in the oxidation furnace, the temperature of the oxidizing gas, the flow amount and the oxidation time are the same in the first oxidation step and the second oxidation step. By this, the oxidation step for forming the oxidized constricting layer 14 is completed.

Also, in the second oxidation step, the oxidation rate of the wafer 1 is greater on the upstream side of the oxidizing gas than the downstream side, like in the first oxidation step. This difference in the oxidation rate equally corresponds to the state of distribution of the oxidation rate at each section of the wafer 1 in the first oxidation step. For this reason, the oxidation progresses in the second oxidation step in a manner to cancel out the difference in the oxidation rate among the different sections of the wafer 1 which occurred in the first oxidation step. Therefore, upon completion of the second oxidation step, the oxidized constricting apertures of the oxidized constricting layers 14 of the plurality of surface-emitting lasers 100 formed at various positions across the plane of the wafer 1 have sizes that are mutually uniform to one another.

In accordance with the present embodiment, because the oxidation treatment for forming the oxidized constricting layers 14 is performed in divided multiple steps, the uniformity and accuracy of the oxidized constricting apertures of the oxidized constricting layers 14 can be improved, compared to the case where a continuous signal oxidation step is conducted. In other words, in accordance with the present embodiment, the amount of oxidation at each of the sections across the entire wafer 1 can be made uniform. Also, in accordance with the present embodiment, the flow direction of oxidizing gas can be changed through 180 degrees with respect to the wafer 1, without implementing a special modification on the manufacturing apparatus such as the oxidation furnace. Also, in accordance with the present embodiment, by conducting the first oxidation step and the second oxidation step, the temperature of the stage in the oxidation furnace, the oxidizing atmosphere and the temperature distribution can be made uniform, with respect to each of the sections of the wafer 1., Accordingly, in accordance with the present embodiment, by the entirety of the oxidation steps, the oxidation treatment can be uniformly applied entirely across the wafer 1, and the oxidized constricting layers 14 of the surface-emitting lasers 100 to be formed in plurality in the wafer 1 can be accurately formed at low cost.

Also, in accordance with the present embodiment, the oxidation treatment is interrupted between the first oxidation step and the second oxidation step. By this, there is no need to have a high-level apparatus structure that introduces a rotation mechanism while performing a temperature management of the stage within the oxidation furnace during an oxidation process with an oxidizing gas at a high temperature of 400° C. Therefore, efficient surface-emitting lasers 100 can be readily fabricated while suppressing an increase in the cost of the manufacturing apparatus.

Further, an oxidation furnace equipped with a rotation mechanism for rotating a stage may be used as the apparatus for manufacturing semiconductor elements which is used for the manufacturing method in accordance with the present embodiment. It is noted that the stage is disposed inside the oxidation furnace, and serves as a base for mounting the wafer 1. Also, a discharge port of oxidizing gas may be provided inside the oxidation furnace. Accordingly, as the rotation mechanism rotates the stage, the wafer 1 on the stage is rotated, and the orientation of the wafer 1 with respect to the discharge port is changed. The stage may preferably be rotated by the rotation mechanism when the oxidation treatment is interrupted after completing the first oxidation step, and the temperature inside the oxidation furnace sufficiently lowers. This operation may be controlled by a control mechanism provided inside the oxidation furnace or outside the oxidation furnace. As the rotation of the stage is performed in a state that is relatively close to normal temperature, a mechanism that is particularly resistive to high temperatures is not necessary as the rotation mechanism, and therefore the cost of the manufacturing apparatus can be lowered.

Instead of the substrate orientation changing device composed of the stage and the rotation mechanism described above, a substrate orientation changing device of a different type may be used. For example, as the substrate orientation changing device, it is possible to use a device that takes out a wafer 1 disposed in the oxidation furnace from the oxidation furnace, and disposes the wafer 1 again in the oxidation furnace with the orientation of the wafer 1 with respect to the discharge port being changed through 180 degrees. Such a substrate orientation changing device can be formed from an arm type robot. Also, such an arm type robot can be realized by modifying a control program of a conventional robot that is used for moving and transporting wafers 1. Accordingly, by the apparatus for manufacturing semiconductor elements in accordance with the present embodiment, the manufacturing apparatus itself can be manufactured at extremely low cost, and high-performance semiconductor elements can be manufactured.

Also, if the substrate orientation changing device composed of a robot is used, the oxidation treatment may preferably be interrupted after completion of the first oxidation step, and the orientation of the wafer 1 may preferably be changed when the temperature within the oxidation furnace sufficiently lowers. By so doing, a mechanism that is particularly resistive to high temperatures is not necessary as the robot arm, and therefore the cost of the manufacturing apparatus can be lowered.

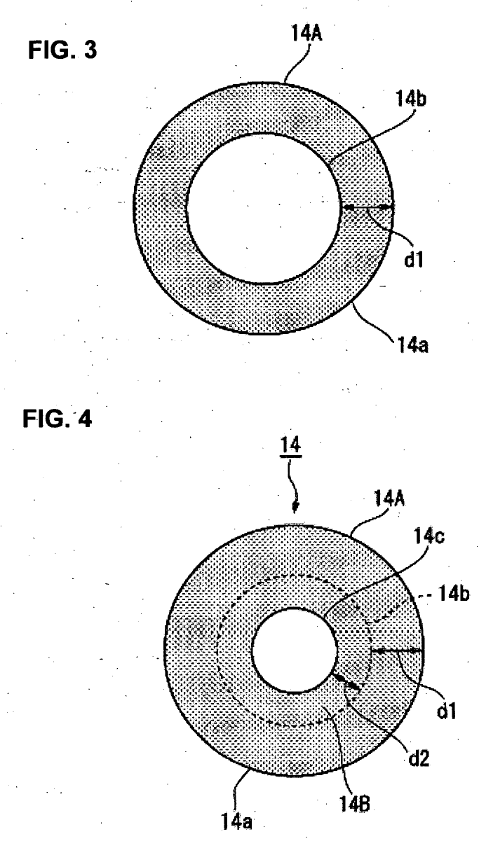

FIG. 3 is a plan view showing an example of an oxidized constricting layer 14A formed by the first oxidation step. An outer circumference 14a of the oxidized constricting layer 14A in FIG. 3 corresponds to an outer circumference (outer configuration) of a columnar section (resonator) of a surface-emitting laser 100 shown in FIG. 1. An inner circumference 14b of the oxidized constricting layer 14A is defined by an end point of oxidation that progresses from the outer circumference 14a in the first oxidation step. Accordingly, a distance d1 between the inner circumference 14b and the outer circumference 14a of the oxidized constricting layer 14A represents the amount of oxidation in the first oxidation step. The-distribution of oxidation amounts d1 is not uniform across the entire upper surface of the wafer 1, as indicated in the figure on the left side of FIG. 2.

FIG. 4 is a plan view of an example of an oxidized constricting layer 14 that is formed by the first oxidation step and the second oxidation step. The oxidized constricting layer 14 is composed of the oxidized constricting layer 14A shown in FIG. 3 and an oxidized constricting layer 14B that is formed inside the oxidized constricting layer 14A. The oxidized constricting layer 14B is formed by the second oxidation step. In other words, an outer circumference of the oxidized constricting layer 14B corresponds to the inner circumference 14b of the oxidized constricting layer 14A. An inner circumference 14c of the oxidized constricting layer 14B defines an end point of oxidation that progresses further inward from the inner circumference 14b in the second oxidation step. Accordingly, a distance d2 between the inner circumference 14b and the inner circumference 14c represents the oxidation amount in the second oxidation step.

The distance d1 and the distance d2 may become generally the same. Differences in the oxidation amount (d1) in the first oxidation step at various sections of the wafer 1 are cancelled out by the oxidation amount (d2) in the first oxidation step. Therefore, in accordance with the present embodiment, when the first oxidation step and the second oxidation step are completed, the distribution of the oxidation amounts (each being d1+d2) across the entire upper surface of the wafer 1 can be made uniform. Consequently, oxidized constricting layers 14 each having a desired oxidized constricting aperture diameter can be highly accurately fabricated.

(Inspection of Oxidation Amount)

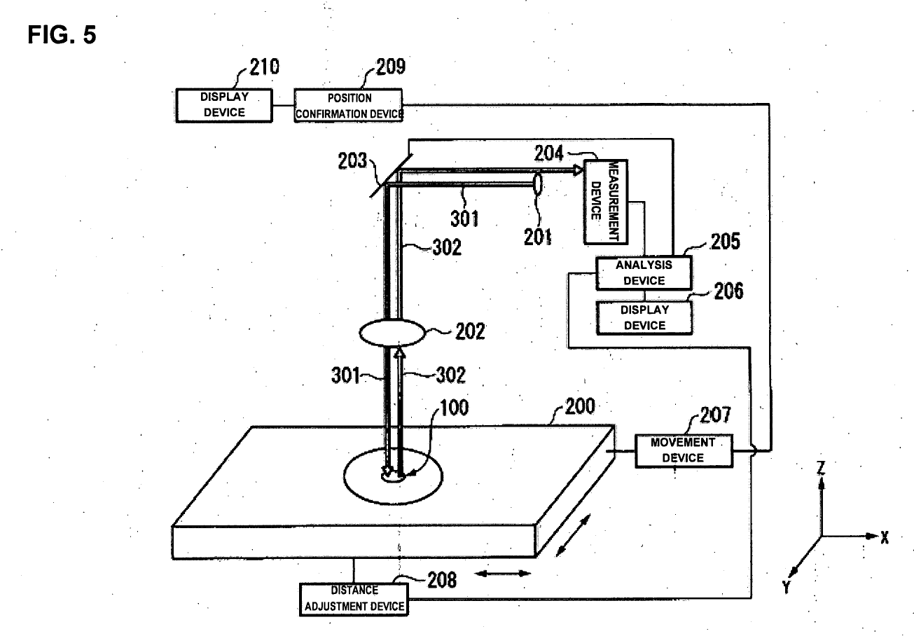

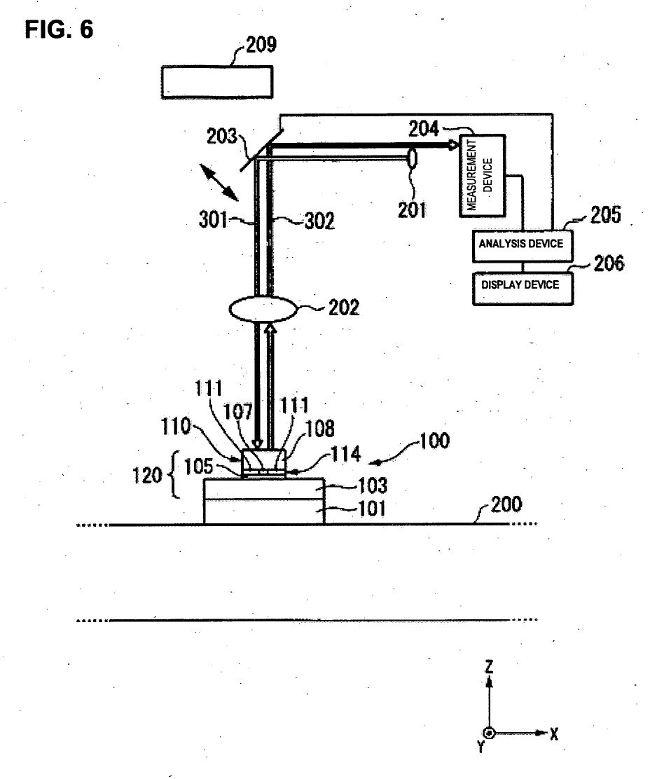

FIG. 5 is a schematic diagram showing an oxidation amount inspection apparatus that is used in the method for manufacturing semiconductor elements in accordance with an embodiment of the invention. FIG. 6 is a partially enlarged view of the oxidation amount inspection apparatus of FIG. 5, which shows a portion near the surface-emitting laser being enlarged. Inspection using the oxidation amount inspection apparatus may preferably be conducted after completion of the first oxidation step indicated in FIG. 2 and before starting of the second oxidation step.

First, the structure of a surface-emitting laser 100 to be inspected is described. The surface-emitting laser 100 corresponds to the surface-emitting laser 100 shown in FIG. 1. As shown in FIG. 2, the surface-emitting laser 100 includes a vertical resonator (hereafter referred to as a “resonator”) 120 formed on a semiconductor substrate 101 (which corresponds to the semiconductor-substrate 11). The re sonator 120 is formed from a lower mirror 103 (that corresponds to the lower DBR 12), an active layer 105 (that corresponds to the active layer 13), and an upper mirror 108 (that corresponds to the upper DBR) sequentially laminated over the semiconductor substrate 101.

The lower mirror 103 is formed on the semiconductor substrate 101, and is composed of a distributed reflection type multilayer mirror of 40 pairs of alternately laminated n-type Al_{0.9}Ga_{0.1}As layers and n-type Al_{0.15}Ga_{0.85}As layers. The active layer 103 is formed on the lower mirror 103, and is composed of GaAs well layers and Al_{0.3}Ga_{0.7}As barrier layers in which the well layers include a multiple quantum well structure composed of three layers. The upper mirror 108 is formed on the active layer 105, and is composed of a distributed reflection type multilayer mirror of 25 pairs of alternately laminated p-type Al_{0.9}Ga_{0.1}As layers and p-type Al_{0.5}Ga_{0.85}As layers.

The upper mirror 108 is made to be p-type by doping Zn, and the lower mirror 103 is made to be n-type by doping Si. Accordingly, the upper mirror 108, the active layer that is not doped with an impurity, and the lower mirror 103 form a pin diode.

Also, the vertical resonator 120 includes a columnar semiconductor deposited body (columnar section) 110 formed therein. The columnar section 110 is formed by etching a portion of the resonator 120 extending from a laser light emission side of the surface-emitting type element 100 to an intermediate point of the lower mirror 103 in a circular shape as viewed from the laser emission side. The present embodiment is described as to a case where the plane configuration of the columnar section 110 is in a circular shape, but the plane configuration of the columnar section 110 can be in any arbitrary shape. It is noted here that the columnar section 110 refers to a portion of the resonator 120, which is a columnar semiconductor laminated body including at least the upper mirror 108, a current constricting layer 114 and the active layer 120. Moreover, a contact layer (not shown) composed of p-type GaAs is formed on the upper mirror 108 of the columnar section 110.

The current constricting layer 114 (that corresponds to the oxidized constricting layer 14A in FIG. 3) is formed to achieve an effective injection of current in the active layer 105. It is assumed now that the current constricting layer 114 is formed by the first oxidation step indicated on the left side of FIG. 2. The current constricting layer 114 may include, for example, an aperture portion 107 composed of a p-type AlAs layer, and an oxidized portion 111 formed around the aperture portion 107. To form the current constricting layer 114, an AlAs layer is formed in advance in the upper mirror 108 near the active layer 105, and then the AlAs layer is exposed to a water vapor atmosphere at about 400° C. at its side surface. By this step (first oxidation step), the AlAs layer is oxidized, such that the oxidized portion (a portion including aluminum oxide) becomes to be the oxidized portion 111, and a portion that remains without being oxidized becomes to be the aperture portion 107. In other words, in this step, the AlAs layer is oxidized inward from its circumference, whereby aluminum oxide that is a dielectric material is formed, and a portion including the aluminum oxide becomes to be the oxidized portion 111.

As described above, the diameter (oxidized constricting aperture diameter) and the configuration of the aperture portion 107 greatly affect the emission efficiency and the emission pattern of the element, and therefore it is very important to measure the diameter and configuration of the aperture portion 107. In the present embodiment, description is made as to an example of measuring the diameter (oxidized constricting aperture diameter) and the configuration of the aperture portion 107 by the oxidation amount inspection apparatus.

It is noted that the present embodiment shows the case where the surface-emitting laser 100 to be inspected is still a device that is in the process of being fabricated. More concretely, the present embodiment shows the case where the surface-emitting laser 100 to be inspected is still a device in a state before a pair of electrodes (which correspond to the first electrode 17 and the second electrode 18) for injecting a current in the active layer 105 is formed. By inspecting the device in this state, the inspection can be performed without being affected by reflected light from electrodes, such that the diameter and configuration of the aperture portion 107 can be accurately measured. It is noted here that, at which of the stages in forming the surface-emitting laser 100 the method of inspecting the oxidizing amount of the present embodiment should be applied to the surface-emitting laser 100 is not particularly limited, and it is acceptable as long as the method is applied after the oxidized constricting layer 114 (which corresponds to the oxidized constricting layer 14A in FIG. 3) is formed in the columnar section 110.

After the diameter (current constricting aperture diameter) and the configuration (formed state of the oxidized layer) of the aperture portion 107 of the surface-emitting laser 100 shown in FIG. 5 are measured by the inspection method according to the present embodiment, the second oxidation step indicated in FIG. 2 is conducted. It is noted that parameters of the second oxidation step may preferably be adjusted based on the inspection result. As the parameters of the second oxidation step, the oxidation time of the oxidation step, the flow amount of oxidizing gas, the temperature of the oxidizing gas and the like can be enumerated.

(Surface-Emitting Laser Inspection Apparatus)

Next, an inspection apparatus for inspecting the surface-emitting laser 100 in accordance with the present embodiment is described.

As shown in FIG. 5 and FIG. 6, the inspection apparatus in accordance with the present embodiment includes a test piece stage 200, a movement mechanism 207 that moves the test piece stage 200, a laser light source 201, an optical system 202 that focuses the laser light, a distance adjustment device 208 that adjusts the distance between the surface-emitting laser 100 and the optical system 202, a scanning device 203 that two-dimensionally scans laser light 301 in a plane parallel with the surface of the semiconductor substrate 101, an inspection device 204 that measures the amount of reflected light 302 from an object to which the laser light 301 is irradiated, an analysis device 205 that constructs a two-dimensional distribution of the amount of reflected light measured by the inspection device 204, and a display device 206 that displays the two-dimensional distribution of the amount of reflected light. In the present embodiment, the surface of the semiconductor substrate 101 is in parallel with an X-Y plane in FIG. 5.

The test piece stage 200 is a stage on which the surface-emitting laser 100 to be inspected is disposed. As shown in FIG. 6, the surface-emitting laser 100 is disposed in a manner that a back surface of the semiconductor substrate 101 (a surface on the opposite side of the surface where the resonator 120 is formed) is in contact with the test piece stage 200.

The movement mechanism 207, as shown in FIG. 6, is a mechanism that moves the test piece stage 200 in a direction parallel to the surface of the semiconductor substrate 101, in other words, in a direction parallel to the X-Y plane in FIG. 5. In the inspection apparatus in accordance with the present embodiment, the movement mechanism 207 has functions to move the test piece stage 200 in directions parallel to each of the X-direction and Y-direction. In the movement mechanism 207, movement of the test piece stage 200 can be carried out manually or automatically. By moving the test piece stage 200 in this way, the position of the surface-emitting laser 100 in a plane parallel to the X-Y plane can be adjusted.

In the inspection apparatus in accordance with the present embodiment, furthermore, as shown in FIG. 5, a position confirmation device 209 is formed in order to check the position of the surface-emitting laser 100 in a plane parallel to the surface of the semiconductor substrate 101. The position confirmation device 209 images the surface-emitting laser 100 to be inspected, to thereby confirm the position of the surface-emitting laser 100 in a plane parallel to the X-Y plane in FIG. 5. As the position confirmation device 209, for example, a CCD camera may be used. The image content captured by the position confirmation device 209 is displayed on a display section 210, such as, for example, a display device.

Based on information obtained from the position confirmation device 209, the movement mechanism 207 moves the test piece stage 200 in respective directions parallel to the X-direction and Y-direction, in order to position the surface-emitting laser 100 at a predetermined position.

The laser light source 201 irradiates the surface-emitting laser 100 with laser light 301 from the side on which the columnar section 110 is formed, in the direction perpendicular to the surface of the semiconductor substrate 101. As the laser light 301, a laser light with a single wavelength can be used. By determining the shape of the aperture portion 107 from the amount of reflected light obtained from irradiating the surface-emitting laser 100 with the single-wavelength laser light 301, a clear image of the current constricting layer 114 can be obtained from the inspection result, which is less susceptible to the influence of noise components such as ambient light or the like. As a result, the aperture diameter and shape of the aperture portion 107 can be accurately measured.

Also, when electrodes are formed in the surface-emitting laser. 100 and then the surface-emitting laser 100 is driven, the laser light 301 emitted from the laser light source 201 may have a wavelength shorter than the wavelength of the laser light emitted by the surface-emitting laser. In other words, in the present embodiment, the aperture diameter and shape of the aperture portion 107 are measured based on the difference between the amount of reflected light from the aperture portion 107.and the amount of reflected light from the oxidized portion 111, the measurement is possible even with a very small amount of reflected light. Therefore, the measurement is possible even when a laser light with a short wavelength is used, which would be absorbed within the surface-emitting laser 100, and for which a high intensity is difficult to obtain. Since the resolving power can be increased by using a laser light with a shorter wavelength, the aperture diameter and shape of the aperture portion 107 can be accurately measured. For example, in the present embodiment, a laser light with a wavelength of 650 nm can be used as the laser light 301.

The optical system 202 has a function to focus the laser light 301. In the inspection apparatus of the present embodiment, the optical system 202 functions to focus the laser light 301 emitted from the laser light source 201 on the cross-section of the oxidized constricting layer 114.

The distance adjustment device 208 adjusts the distance between the surface-emitting laser 100 and the optical system 202. In the inspection apparatus of the present embodiment, the scanning device 203 performs two-dimensional scanning of the laser light 301 in a plane parallel to the surface of the semiconductor substrate 101, while the distance adjustment device 208 varies the distance between the surface-emitting laser 100 and the optical system 202, and the distance adjustment device 208 fixes the distance at the point at which the difference between the amount of reflected light from the oxidized portion 111 and the amount of reflected light from the aperture portion 107 becomes maximum.

The scanning device 203 includes a device to perform two-dimensional scanning of the laser light 301 in a plane parallel to the X-Y plane in FIG. 5. As an example of the scanning device 203, a galvano-scanner can be enumerated. In the present embodiment, the scanning device 203 performs two-dimensional scanning of the laser light 301 for at least the cross-section of the columnar section 110 among a plane parallel to the X-Y plane in FIG. 5. Furthermore, in order to confirm the shape of the resonator 120, the scanning device 203 performs two-dimensional scanning of the laser light 301 in a larger area than the cross-section of the columnar section 110 among a plane parallel to the X-Y plane in FIG. 5.

The inspection device 204 has a device that measures the amount of reflected light from the test piece irradiated with the laser light 301.

The analysis device 205 has a device that produces a two-dimensional distribution based on the amount of reflected light from the test piece irradiated with the laser light 301. The analysis device 205 of the inspection apparatus of the present embodiment obtains a two-dimensional distribution of the amount of reflected light based on the position of the laser light 301 scanned by the scanning device 203 and the amount of reflected light measured by the inspection device 204, as indicated in FIG. 5.

The display device 206 includes a device displays the two-dimensional distribution obtained by the analysis device 205. As the display device 206, for example, a display may be enumerated.

(Method of Inspecting Surface-Emitting Laser)

Next, a method of inspecting the surface-emitting laser 100 in accordance with the present embodiment using the inspection apparatus shown in FIGS. 5 and 6 is described.

First, the surface-emitting laser 100 is mounted on the test piece stage 200. In this instance, the surface-emitting laser 100 is mounted with the semiconductor substrate 101 being located to the side of the test piece stage 200. Next, using the position detection device 209 shown in FIG. 5, the position of the surface-emitting laser 100 to be inspected is confirmed. Based on information from the position detection device 209, the test piece stage 200 is moved in the X-direction and Y-direction, using the movement mechanism 207 as required, so that the surface-emitting laser 100 is centered in the imaging area. Next, laser light 301 is emitted from the laser light source 201.

Next, the scanning device 203 is operated to perform two-dimensional scanning of the laser light 301 in a plane parallel to the X-Y plane in FIG. 5, while the distance adjustment device 208 is operated to vary the distance between the surface-emitting laser 100 and the optical system 202. In the inspection apparatus of the present embodiment, this distance is fixed at the point at which the difference between the amount of reflected light from the oxidized portion 111 and the amount of reflected light from the aperture portion 107 in the current constricting layer 114 composing the surface-emitting laser 100 becomes maximum, and the inspection device 204 is used to measure the amounts of reflected light. By this method, accurate focusing at a predetermined position of the oxidized constricting layer 114 is possible.

Furthermore, based on the position of the scanning of the laser light 301 performed by the scanning device 203 and the amount of reflected light measured by the inspection device 204, the analysis device 205 obtains a two-dimensional distribution of the amount of reflected light. The two-dimensional distribution is displayed by the display device 206. From this distribution, the aperture -diameter and shape of the aperture portion 107 can be determined.

According to the method and inspection apparatus of inspecting the surface-emitting laser 100 in accordance with the present embodiment, the laser light 301 is irradiated, and the difference in the amount of reflected light is obtained as data, whereby a clear image can be obtained while reducing the susceptibility to the influence of noise components such as ambient light or the like. In this case, even with a very small amount of reflected light, the aperture diameter and the like of the aperture portion 107 can be measured as long as the difference between the amount of reflected light from the oxidized portion 111 and the amount of reflected light from the aperture portion 107 can be detected, and therefore a high output light source is not required. Also, the laser light with which the surface-emitting laser 100 is irradiated may have a wavelength shorter than the wavelength of the laser light emitted by the surface-emitting laser 100.

Since the laser light 301 is focused on the oxidized constricting layer 114 using the optical system 202, the resolution of the image of the oxidized constricting layer 114 can be improved. Since the laser light 301 is focused at a predetermined position of the oxidized constricting layer 114, the amount of reflected light from the unfocused portion, light reflected from the surface of the semiconductor substrate 101 and the like, can be limited. As a result, the aperture diameter and shape of the aperture portion 107 can be accurately measured.

By causing the scanning device 203 to perform two-dimensional scanning of the laser light 301 on at least the cross-section of the columnar section 110 among a plane parallel to the surface of the semiconductor substrate 101 (the X-Y plane in FIG. 5), the overall configuration of the oxidized constricting layer 114 can be accurately determined. By carrying out two-dimensional scanning of the laser light 301 in an area larger than the cross-section of the columnar section 110 among the plane parallel to the surface of the semiconductor substrate 101 (the X-Y plane in FIG. 5), the overall configuration of the oxidized constricting layer 114 occupying the whole resonator 120 can be accurately determined.

Moreover, accurate focusing on the oxidized constricting layer 114 is possible because the scanning device 203 performs two-dimensional scanning of the laser light 301 emitted from the laser light source 301 in the plane parallel to the surface of the semiconductor substrate 101, and the distance adjustment device 208 varies the distance between the surface-emitting laser 101 and the optical system 202 and fixes the distance at the point at which the difference between the amount of reflected light from the oxidized portion 111 and the amount of reflected light from the aperture portion 107 becomes maximum.

(Oxidation Treatment Using Inspection Method and Inspection Apparatus)

Using the inspection method and inspection apparatus shown in FIG. 5 and FIG. 6, the shape and the inner circumference 14a (oxidized constricting aperture diameter) of the oxidized constricting layer 14A formed by the first oxidation step are measured (see FIG. 3). Based on the measurement result, the oxidation time required to obtain a target oxidized constricting aperture diameter (the inner circumference 14c in FIG. 3) (i.e., the process time of the second oxidation step) is calculated. Then, the second oxidation step is performed.

By the process described above, in accordance with the present embodiment, the surface-emitting laser 100 with a uniform and accurate oxidized constricting aperture diameter can be fabricated. In other words, the oxidation rate may slightly differ from one wafer 1 to another, but the oxidation rate (the amount of oxidation for the processing time) can be detected in the middle of the oxidation treatment by the present embodiment. Further, the detected oxidation rate can be fed back to the following oxidation step. Therefore, in accordance with the present embodiment, accurate oxidized constricting aperture diameters can be obtained in any of the wafers 1.

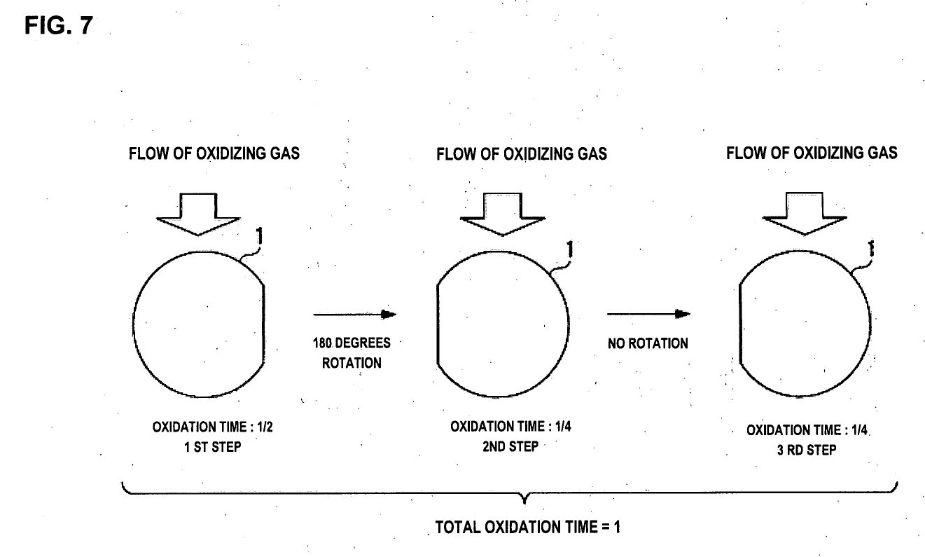

FIG. 7 is a schematic plan view showing a method for manufacturing a surface-emitting laser in accordance with another embodiment of the invention. The manufacturing method shown in FIG. 7 can be understood as a modification of the manufacturing method shown in FIG. 2 or to correspond to the manufacturing method shown in FIG. 2. The manufacturing method of the present embodiment is concretely described below.

FIG. 7 shows oxidation steps for forming an oxidized constricting layer 14 of a surface-emitting laser 100 shown in FIG. 1. The wafer 1 corresponds to the semiconductor substrate 11 shown in FIG. 1. It is assumed that a lower DBR 12, an active layer 13 and an upper DBR 15 composing each resonator of the surface-emitting laser 100 have already been formed on the wafer 1. Also, it is assumed that a cylindrical columnar section, which is formed from the active layer 13 and the upper DBR 15 protruding in a convex shape from the lower DBR 12, has already formed on the wafer 1. It is also assumed that such a columnar section has a very small size, and many of them are formed at-various portions across the entire upper surface of the wafer 1. In other words, numerous resonators of surface-emitting lasers 100 are formed on the upper surface of the wafer 1.

Oxidizing gas indicated in FIG. 7 is a gas with which an oxidation treatment is applied to the wafer 1. In other words, the oxidizing gas is a gas for forming the oxidized constricting layer 14. For example, water vapor at about 400° C. may be used as the oxidizing gas. Then, the oxidizing gas is blown toward the side surface of the wafer 1, and the flow direction of the oxidizing gas is in parallel with the plane direction of the wafer 1.

The figure on the left side of FIG. 7 indicates a first oxidation step, the figure in the center of FIG. 7 indicates a second oxidation step, and the figure on the right side of FIG. 7 indicates a third oxidation step. The first oxidation step is a first oxidation treatment, the second oxidation step is a second oxidation treatment, and the third oxidation step is a third oxidation treatment. In other words, in accordance with the present embodiment, the oxidation process for forming the oxidized constricting layer 14 is conducted in three divided steps for each of the wafers 1.

For example, the first oxidation step performs the oxidation treatment by one half (½) of the entire amount of oxidation. Then, the second oxidation step performs the oxidation treatment by a quarter (¼) of the entire amount of oxidation. Then, the third oxidation step performs the oxidation treatment by a quarter (¼) of the entire amount of oxidation, thereby completing the oxidized constricting layer 14 shown in FIG. 1. When the oxidation time for the entire process from the first to third steps is assumed to be “1,” the oxidation time of the first oxidation step is ½, the oxidation time for the second oxidation step is ¼, and the oxidation time for the third oxidation step is ¼.

Concretely, first, the wafer 1 is placed in an oxidation furnace (not shown), and the first oxidation step that is the first step indicated in FIG. 7 is performed. By this, one half of the oxidation step for forming the oxidized constricting layer 14 is progressed. After the first oxidation step, discharge of the oxidizing gas inside the oxidation furnace is stopped, thereby interrupting the oxidation step. Then, the wafer 1 is removed from the oxidation furnace. The state (the size and the like) of the oxidized layer formed in the wafer 1 is measured by a microscope or the like. For example, the aperture diameter (oxidized constricting aperture diameter) of the oxidized constricting layer formed in the columnar section of the surface-emitting laser in the wafer 1 is measured.

Then, the wafer 1 is rotated through 180 degrees about a center axis orthogonal to the plane of the wafer 1 as a reference axis with the disposed position of the wafer 1 in the first oxidation step as a reference position, and the wafer 1 in this state is inserted the oxidation furnace again. By this, the wafer 1 is disposed in the oxidation furnace, rotated through 180 degrees (i.e., with its front and-rear being inverted) with respect to the flow direction of oxidizing gas (i.e., the discharge port). Accordingly, at the beginning of this placement, the area with a smaller amount of oxidation is positioned in the upstream of the oxidizing gas, and the area with a greater amount of oxidation is positioned in the downstream of the oxidizing gas flow.

In this state, the second oxidation step that is the second step is applied to the wafer 1. The second oxidation step is the same as the first oxidation step as to the discharge state of oxidizing gas in the oxidation furnace. In other words, the discharging position of the oxidizing gas in the oxidation furnace, the temperature of the oxidizing gas, the flow amount and the oxidation time are the same in the first oxidation step and the second oxidation step. By this, the oxidation step for forming the oxidized constricting layer 14 is further progressed by ¼, which amounts to ¾ in progress of the entire oxidation step. After the second oxidation step, discharge of the oxidizing gas inside the oxidation furnace is stopped, thereby interrupting the oxidation step. Then, the wafer 1 is removed from the oxidation furnace. The state (the size and the like) of the oxidized layer formed in the wafer 1 is measured by a microscope or the like. For example, the aperture- diameter (oxidized constricting aperture diameter) of the oxidized constricting layer formed in the columnar section of the surface-emitting laser in the wafer 1 is measured.

Then, the wafer 1 is placed in the oxidation furnace in a manner that the wafer 1 is placed in the same way of placement in the oxidation furnace as in the second oxidation step. In other words, the wafer 1 is placed in the same orientation in the second and third steps with respect to the flow direction of the oxidizing gas as a reference.

In this state, the third oxidation step is applied to the wafer 1. The third oxidation step is the same as the first and second oxidation steps as to the discharge state of oxidizing gas in the oxidation furnace. By this, the oxidation step for forming the oxidized constricting layer 14 is further progressed by ¼, which amounts to 4/4 in progress in total, whereby the oxidation process for forming the oxidized constricting layer 14 is completed.

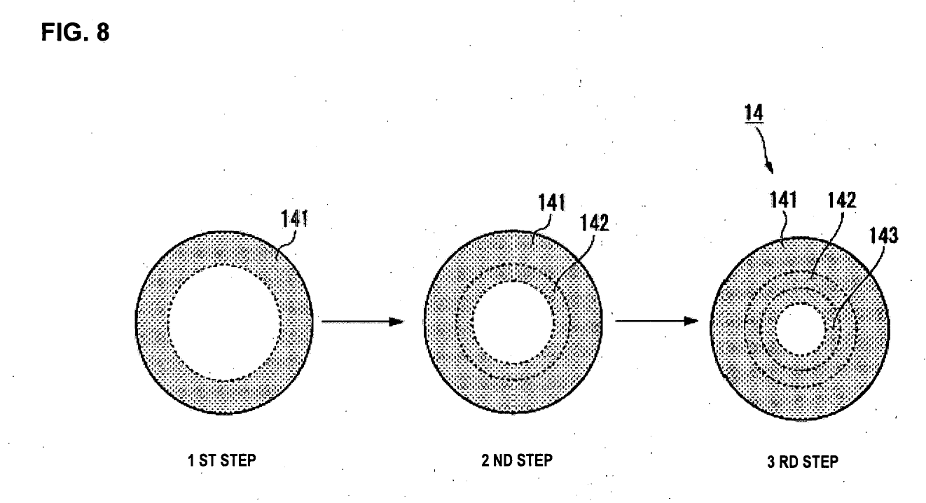

FIG. 8 shows plan views of an example of the oxidized constricting layer 14 formed in the first through third oxidation steps, respectively, in accordance with the present embodiment. First, an oxidized constricting layer 141 is formed by the first oxidation step. An outer circumference of the oxidized constricting layer 141 corresponds to an outer circumference of the columnar section of the surface-emitting laser 100 shown in FIG. 1. Then, an oxidized constricting layer 142 is formed by the second oxidation step. The oxidized constricting layer 142 is formed inside the oxidized constricting layer 141. Then, an oxidized constricting layer 143 is formed by the third oxidation step. The oxidized constricting layer 143 is formed inside the oxidized constricting layer 142. By these steps, the oxidized constricting layer 14 is completed.

In accordance with the present embodiment, since the oxidation process is divided in three steps, the oxidation time for the third oxidation step can be made shorter compared to each of the steps in the case where the oxidation process is divided in two steps as shown in FIG. 2. Therefore, by the manufacturing method in accordance with the present embodiment, an error in the oxidation time can be reduced, compared to the case where the oxidation process is divided in two steps.

Also, in the manufacturing method in accordance with the present embodiment, based on the measured value of the amount of oxidation after the first oxidation step (for example, the inner diameter of the oxidized constricting layer 141 of FIG. 8) and the measured value of the amount of oxidation after the second oxidation step (for example, the inner diameter of the oxidized constricting layer 142 of FIG. 8), the oxidation time for the third oxidation step (or other oxidation parameters) may preferably be finely adjusted. By do doing, the oxidation time for the third oxidation step can be finely adjusted based on the oxidation rate in the second oxidation step, such that the oxidized constricting layer 14 in a desired configuration can be more accurately formed. It is noted here that the oxidation rate in the second oxidation step can be calculated based on the difference between the inner diameter of the oxidized constricting layer 141 and the inner diameter of the oxidized constricting layer 142 in FIG. 8, the oxidation time for the second oxidation step and the like.

Also, in the manufacturing method of the present embodiment, the orientation of the wafer 1 is rotated through 180 degrees when the first oxidation step shifts to the second oxidation step. However, the orientation of the wafer 1 may be rotated through 120 degrees when the first oxidation step shifts to the second oxidation step, and the orientation of the wafer 1 may be further rotated through 120 degrees when the second oxidation step shifts to the third oxidation step.

Further, the time division of each of the oxidation steps is not limited to “½: ¼: ¼,” and may be “½: ½: α,” where α may preferably be a value sufficiently smaller than ½ (for example, less than 1/10). In this case, the third oxidation step is conducted as a step to finely adjust the amount of oxidation.

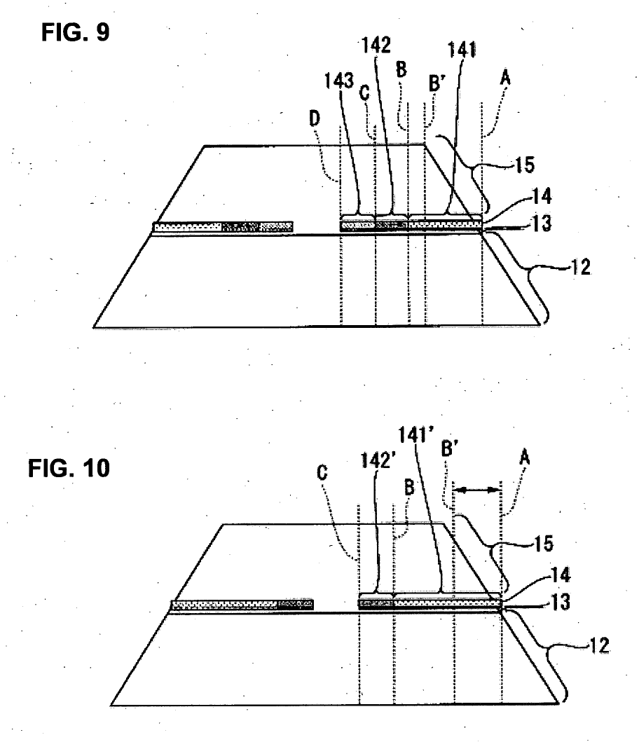

FIG. 9 schematically shows a cross-sectional view showing the method for manufacturing the surface-emitting laser shown in FIG. 7 and FIG. 8. FIG. 9 shows the columnar section in the surface-emitting laser 100 shown in FIG. 1. Also, components in FIG. 9 that are the same as those of the surface-emitting laser 100 shown in FIG. 1 are appended with the same reference numerals. The columnar section of the surface-emitting laser 100 has a trapezoidal cross-sectional configuration.

In the manufacturing method shown in FIG. 7 and FIG. 8, the oxidized constricting layer 141, which extends from the side surface (position A) of the columnar section to position B within the columnar section, is formed in the first oxidation step. In the second oxidation step, the oxidized constricting layer 142 is formed, extending from position B to position C within the columnar section. In the third oxidation step, the oxidized constricting layer 143 is formed, extending from position C to position D within the columnar section, whereby the oxidized constricting layer 14 is completed.

In the manufacturing method described above, the oxidized layer may preferably be formed, in the first oxidation step, from the side surface (position A) of the columnar section to position B that is located inside a region (extending from position A to position B′) shaded by the sloped side of the columnar section as the columnar section is viewed from above.

By so doing, position B that is the start point of the oxidized layer formed in the second oxidation step and position C that is the end point of the oxidized layer formed in the second oxidation step are located outside the shaded region (extending from position A to position B′) of the closed side of the columnar section. Accordingly, the start point. (position B) and the end point (position C) of the second oxidation step can be accurately measured by a microscope or the like. Therefore, the amount of oxidation (the oxidation rate) in the second oxidation step can be accurately measured, and therefore the oxidized constricting layer 14 of the surface-emitting laser can be accurately formed.

FIG. 10 schematically shows a cross-sectional view showing one example of a manufacturing method when the process of forming the oxidized constricting layer 14 is divided in two steps. Components in FIG. 10 that are the same as those of the surface-emitting laser 100 shown in FIG. 1 are appended with the same reference numerals. In the first oxidation step, an oxidized constricting layer 141′, which extends from the side surface (position A) of the columnar section to position B within the columnar section, is formed. In the second oxidation step, an oxidized constricting layer 142′ is formed, extending from position B to position C within the columnar section, whereby the oxidized constricting layer 14 is completed.

When the oxidation rate in the first oxidation step is detected in this manufacturing method, the distance between position A and position B needs to be measured. However, because the columnar section is trapezoidal, it is difficult to inspect position A on the side surface by a microscope or the like. Alternatively, the oxidation amount in the first oxidation step may be measured with position B set at a corner of the trapezoid of the columnar section as a reference. However, it becomes difficult to inspect position B by a microscope or the like. Accordingly, in the manufacturing method shown in FIG. 10, accurate measurement of the oxidation rate in the first oxidation step is difficult, and therefore the oxidized constricting layer 14 cannot be accurately formed just as the manufacturing method shown in FIG. 7 through FIG. 9 does.

It is noted that the technical scope of the invention is not limited to the embodiments described above, and many modifications can be made without departing from the subject matter of the invention. Also, the concrete materials, layered compositions and the like cited in the embodiments are merely part of examples and can be appropriately modified.

It should be noted that, for example, interchanging the p-type and n-type characteristics of each of the semiconductor layers in the above described embodiments does not deviate from the subject matter of the invention. In the above described embodiments, the description is made as to an AlGaAs type, but depending on the oscillation wavelength to be generated, other materials, such as, for example, GaInNAs type, GaAsSb type, and GaInP type semiconductor materials can also be used.

Also, the cross-sectional shape of the columnar section of the surface-emitting laser to which the invention is applicable is not necessarily trapezoidal, and the invention is also applicable to a cross-sectional shape in which an upper surface of a columnar section is angled with respect to a bottom surface of the columnar section.

Further, surface-emitting lasers to which the invention is applicable may not necessarily be in a structure having a columnar section. For example, a surface-emitting laser may be manufactured by a method in which a lower DBR 12, an active layer 13 and an upper DBR 15 are sequentially formed on a semiconductor substrate, a bore extending from the upper DBR 15 to the active layer 13 (or to a portion of the lower DBR 12) is formed from above the semiconductor substrate, and an oxidation treatment is conducted to thereby form a current constricting layer (from a portion of the side surface of the bore). Such a method for manufacturing a surface-emitting laser is also applicable in accordance with an embodiment of the invention.

Also, in the embodiments described above, the surface-emitting laser having a single columnar section is shown as an object to be measured. However, the mode of the invention would not be harmed if columnar sections are provided in plurality within a substrate.

Also, semiconductor elements in accordance with the embodiments of the invention may be widely applied to electronic apparatuses using light. For example, as application circuits and electronic apparatuses equipped with semiconductor elements in accordance with any one of the embodiments of the invention, optical interconnection circuits, optical fiber communications modules, laser printers, laser beam projectors, laser beam scanners, linear encoders, rotary encoders, displacement sensors, pressure sensors, gas sensors, blood flow sensors, finger print sensors, high-speed electric modulation circuits, wireless RF circuits, cellular phones, wireless LANs and the like can be enumerated.

Furthermore, semiconductor elements in accordance with the embodiments of the invention are not limited to optical semiconductor elements such as surface-emitting lasers, and the invention is also applicable to various semiconductor elements having oxidized films. Also, the invention is applicable to a variety of methods and apparatuses for manufacturing semiconductor elements including optical semiconductor elements.

What is claimed is:

1. A method for manufacturing a semiconductor element comprising an oxidation process of forming an oxidized layer in a semiconductor substrate by an oxidizing gas, wherein the oxidation process is conducted for the semiconductor substrate in a plurality of divided steps.

2. A method for manufacturing a semiconductor element according to claim 1, wherein the plurality of oxidation steps includes a first oxidation step and a second oxidation step, wherein a flow direction of oxidizing gas with respect to the semiconductor substrate in the first oxidation step is different from a flow direction of the oxidizing gas with respect to the semiconductor substrate in the second oxidation step.

3. A method for manufacturing a semiconductor element according to claim 2, wherein, in the first oxidation step and the second oxidation step, the flow direction of the oxidizing gas is different through 180 degrees from each other.

4. A method for manufacturing a semiconductor element according to claim 2, wherein the oxidation process includes the steps of inserting the semiconductor substrate in an oxidation furnace and flowing an oxidizing gas in the oxidation furnace, wherein the semiconductor substrate is removed from the oxidation furnace after the first oxidation step, the semiconductor substrate is placed again in the oxidation furnace in a manner that the orientation of the semiconductor substrate is 180 degrees different from the orientation of the semiconductor substrate in the oxidation furnace in the first oxidation step, and then the second oxidation step is conducted.

5. A method for manufacturing a semiconductor element according to claim 2, wherein a period to interrupt formation of an oxidized layer by the oxidizing gas is provided between the first oxidation step and the second oxidation step.

6. A method for manufacturing a semiconductor element according to claim 1, wherein the semiconductor substrate has a compound semiconductor layer, and the oxidized layer is formed in the compound semiconductor layer by the oxidation process.

7. A method for manufacturing a semiconductor element according to claim 1, wherein the semiconductor element is a surface-emitting laser, and the oxidized layer defines an oxidized constricting layer of the surface-emitting laser.

8. A method for manufacturing a semiconductor element according to claim 1, comprising a measurement step of inspecting a formed state of the oxidized layer during the plurality of oxidation steps.

9. A method for manufacturing a semiconductor element according to claim 8, wherein a parameter of one of the oxidation steps to be conducted after the measurement step is controlled based on a result of inspection obtained by the measurement step.

10. A method for manufacturing a semiconductor element according to claim 9, wherein the parameter of the oxidation process is at least one of an oxidation time for each the oxidation steps, a flow amount of the oxidizing gas, and a temperature of the oxidizing gas.

11. An apparatus for manufacturing a semiconductor element comprising an oxidation furnace in which a semiconductor substrate is placed, wherein the oxidation furnace has a discharge port for discharging an oxidizing gas inside the oxidation furnace, and a substrate orientation changing device that changes the orientation of the semiconductor substrate inside the oxidation furnace with respect to the discharge port as a reference.

12. An apparatus for manufacturing a semiconductor element according to claim 11, wherein the substrate orientation changing device takes out the semiconductor substrate disposed inside the oxidation furnace from the oxidation furnace, changes the orientation of the semiconductor substrate with respect to the discharge port through 180 degrees, and disposes the semiconductor substrate again in the oxidation furnace, during the oxidation process that is applied to the semiconductor substrate in the oxidation furnace.

13. An apparatus for manufacturing a semiconductor element according to claim 11, wherein the oxidation furnace stops supplying the oxidizing gas before the orientation of the semiconductor substrate is changed by the substrate orientation changing device, and restarts supplying the oxidizing gas after the orientation of the semiconductor substrate is changed by the substrate orientation changing device.

14. An apparatus for manufacturing a semiconductor device according to claim 11, wherein the substrate orientation changing device includes a stage that is disposed inside the oxidation furnace for mounting the semiconductor substrate thereon, a rotation device that changes the orientation of the stage with respect to the discharge port, and a control device that operates the rotation device when an internal temperature of the oxidation furnace is lowered to a predetermined value during the oxidation process applied to the semiconductor substrate.

15. A semiconductor element is manufactured by using the apparatus for manufacturing a semiconductor element recited in claim 11.

16. A method for manufacturing a semiconductor element according to claim 1, wherein the plurality of oxidation steps includes a first oxidation step, a second oxidation step that is performed after the first oxidation step, and a third oxidation step that is performed after the second oxidation step, wherein the flow direction of the oxidizing gas with respect to the semiconductor substrate in the first oxidation step is different from the flow direction of the oxidizing gas with respect to the semiconductor substrate in the second oxidation step, and a measurement step of inspecting a forming state of the oxidized layer is conducted before the third oxidation step.

17. A method for manufacturing a semiconductor element according to claim 16, wherein an oxidation time of the third oxidation step is shorter than the oxidation time of the first oxidation step.

18. A method for manufacturing a semiconductor element according to claim 17, wherein the semiconductor element is a surface-emitting laser, the surface-emitting laser has a columnar section having a trapezoidal cross-sectional shape, the oxidized layer defines an oxidized constricting layer that is formed inside the columnar section of the surface-emitting laser, wherein, in the first oxidation step, the oxidized layer is formed up to a position inside a region shaded by a sloped side of the columnar section as the columnar section is viewed from above.

19. A method for manufacturing a semiconductor element according to claim 18, wherein the measurement step includes inspecting at least a position of an end section of the oxidized layer formed by the first oxidation step and a position of an end section of the oxidized layer formed by the second oxidation step, and the third oxidation step is performed with parameters for oxidation being adjusted based on an inspection result of the measurement step.

20. A semiconductor element manufactured by the method for manufacturing a semiconductor element recited in claim 1.
